(19) United States
(12) Patent Application Publication
(10) Pub. No.: US 2011/0116537 A1
(43) Pub. Date: May 19, 2011

(54) SIGNAL DISCRIMINATING METHOD OF ELINT RECEIVER

(75) Inventor: Ji Hoon Jung, Yongin (KR)

(73) Assignee: LIG Nex1 Co., Ltd., Seoul (KR)

(21) Appl. No.: 12/944,645

(22) Filed: Nov. 11, 2010

(30) Foreign Application Priority Data
Nov. 13, 2009 (KR) 10-2009-0109817

(51) Int. Cl. H03K 9/00; H03K 9/08

(52) U.S. Cl. 375/238; 375/316

(57) ABSTRACT

Provided is a signal discriminating method of an electronic intelligence receiver. The method includes: detecting a start time and an end time of modulation on pulse (MOP) due to a direct path signal and a multi path signal from a received signal; and extracting at least one of signal strength, frequency, and phase by using in-phase component and quadrature component of the signal in a time from a start time of the signal to a start time of the MOP. As a result, the present invention can prevent faulty discrimination or no discrimination of a signal due to a multi path signal and an unintended MOP to extract signal parameters.

### BACKGROUND OF THE INVENTION

1. Field of the Invention

The present invention relates to an electronic warfare, and more particularly, to a signal discriminating method of an electronic intelligence receiver capable of preventing faulty discrimination or no discrimination of a signal due to a multi-path signal and an unintended MOP.

2. Description of the Related Art

An electronic warfare (EW) implies a general military action searching or reversely using an electronic wave used by an enemy to degrade an effect of military action of an enemy and protecting the use of electronic wave of allied ground forces from being hindered by an enemy. A kind of a weapon using an electronic wave is very various from terrestrial communication devices to various kinds of radars or missiles. Further, the operation frequency band of the weapon is very wide. In addition, it is general that the electronic warfare includes weapons using electronic wave signals as well as infrared rays or laser signals, etc., in a broad sense.

The receiver used in the electronic warfare may be classified into several types of receivers according to application fields. The kind of main receivers may include a radar warning receiver (RWR), an electronic support (ES) receiver, and an electronic intelligence (ELINT) receiver, or the like.

Among those, the electronic intelligence receiver, which is a receiver taking charge of a reconnaissance mission, has a high sensitive receiving function capable of performing a high-accurate and remote search and a precise signal analysis, rather than a rapid search. The electronic intelligence receiver measures frequency, time of arrival, pulse width, signal strength, modulation characteristics in a pulse, etc., for a received signal (for example, a radar signal), thereby generating a pulse description word (PDW). The collected PDW is grouped based on the frequency, the pulse width, the signal strength, etc., to analyze the time and frequency relationship between the pulses in each group, thereby extracting the characteristic information of a pulse string.

However, a direct path signal radiated from an emitter and directly reached in the electronic intelligence receiver as well as a multi path signal reached by being radiated from the emitter and reflected from other objects may be received. When the direction path signal and the multi path signal overlaps with each other, the unintended modulation on pulse (MOP) is generated. In other words, the direct path signal and the multi path signal are subjected to amplitude modulation, phase modulation, or frequency modulation, thereby generating amplitude modulation on pulse (AMOP), pulse modulation on pulse (PMOP), or frequency modulation on pulse (FMOP). The unintended modulation on pulse leads to the faulty discrimination or no discrimination for a threat signal.

### SUMMARY OF THE INVENTION

The present invention has been made in an effort to provide a signal discriminating method of an electronic intelligence receiver capable of preventing faulty discrimination or no discrimination of a signal due to a multi path signal and an unintended MOP to extract signal parameters.

An exemplary embodiment of the present invention provides a signal discriminating method of an electronic intelligence receiver, the method including: (a) detecting a start time and an end time of modulation on pulse (MOP) due to a direct path signal and a multi path signal from a received signal; and (b) extracting at least one of signal strength, frequency, and phase by using in-phase component and quadrature component of the signal in a time from a start time of the signal to a start time of the MOP.

The signal discriminating method of an electronic intelligence receiver may further include (c) extracting the time from the start time of the signal to the end time of the MOP as the pulse width of the signal.

The signal discriminating method of an electronic intelligence receiver may further include determining the occurrence or not of the MOP.

The step (a) may detect the start time and the end time of the MOP based on the change in signal strength, frequency, and phase extracted using the in-phase component and quadrature component of the signal over the time.

The step (a) may detect the first sudden change time of at least one of the extracted signal strength, frequency, and phase as the start time of the MOP and the second sudden change time thereof as the end time of the MOP.

The signal discriminating method of an electronic intelligence receiver may further include generating a pulse description word (PDW) including the information on the extracted signal strength, frequency, phase, and pulse width.

The PDW may further include information on the occurrence or not of MOP and the start time and the end time of MOP.

Another exemplary embodiment of the present invention provides a recording medium readable with a computer recording a program for executing the signal discriminating method of an electronic intelligence receiver.

The present invention prevents faulty discrimination or no discrimination of a signal by the multi path signal and the unintended MOP, thereby making it possible to extract the signal parameters.

### BRIEF DESCRIPTION OF THE DRAWINGS

FIGS. 1A and 1B are reference diagrams for explaining conditions generating MOP due to the overlapping of a direct path signal with a multi path signal in an electronic intelligence receiver;

FIG. 2 is a flow chart showing the signal discriminating method of the electronic intelligence receiver according to an exemplary embodiment of the present invention;

FIG. 3 is a diagram showing a shape where the MOP occurs due to the direct path signal and the multi path signal;

FIG. 4 shows the structure of the PDW according to an exemplary embodiment of the present invention; and

FIG. 5 is a reference diagram for explaining a process of extracting signal strength, frequency, phase parameters, and pulse width parameters according to an exemplary embodiment of the present invention.

### DETAILED DESCRIPTION OF THE EMBODIMENTS

Hereinafter, exemplary embodiments of the present invention will be described in detail with reference to the accompanying drawings. In the following description and drawings, like components refer to like reference numerals and therefore, the duplicated description thereof will be omitted. In addition, the detailed description of known functions and configurations will be omitted so as not to obscure the subject of the present invention with unnecessary detail.

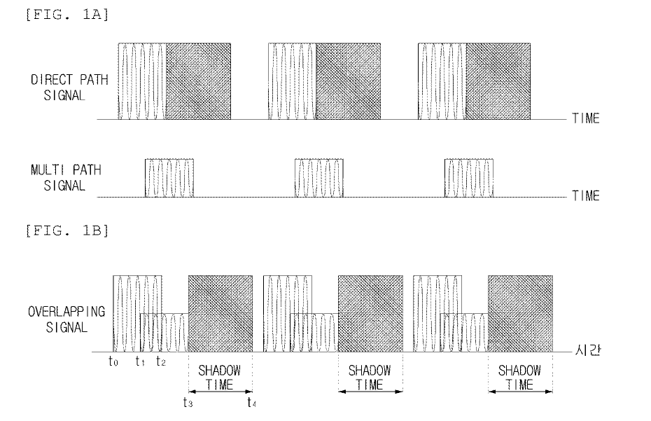

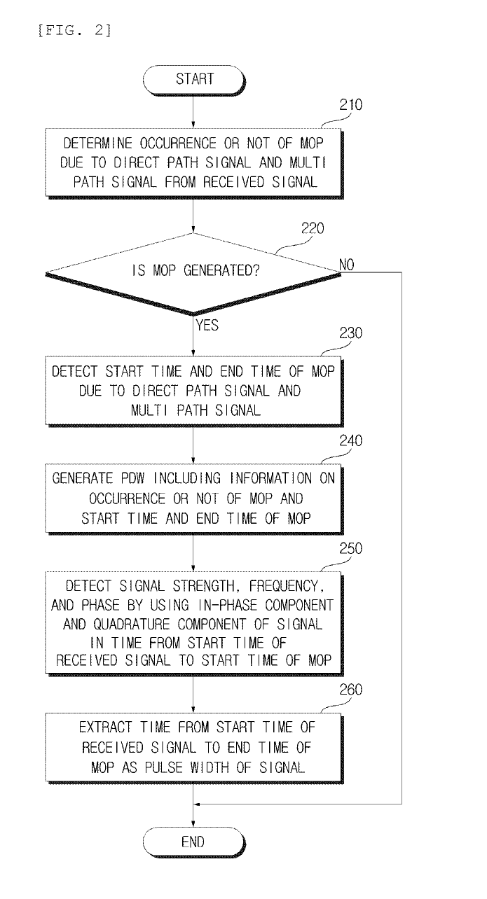

FIGS. 1A and 1B are reference diagrams for explaining conditions generating an MOP due to the overlapping of a direct path signal with a multi path signal in an electronic intelligence receiver.

Referring to FIG. 1A, a direct path signal pulse is periodically received and a predetermined shadow time is generated from an end time of each pulse. In this case, as shown in FIG. 1A, when the multi path signal pulse is received before the direct path signal pulse ends, the MOP occurs. As shown in FIG. 1B, the MOP occurs in the received time t1 to t2 due to the overlapping of the direct path signal pulse and the multi path signal pulse and the predetermined shadow time t3 to t4 occurs from the end time t3 of the multi path signal pulse.

FIG. 2 is a flow chart showing the signal discriminating method of the electronic intelligence receiver according to an exemplary embodiment of the present invention.

First, it is determined whether the MOP occurs from the received signal due to the direct path signal and the multi path signal (S210) and when the MOP occurs (S220), the start time and the end time of the MOP are detected due to direct path signal and the multi path signal (S230).

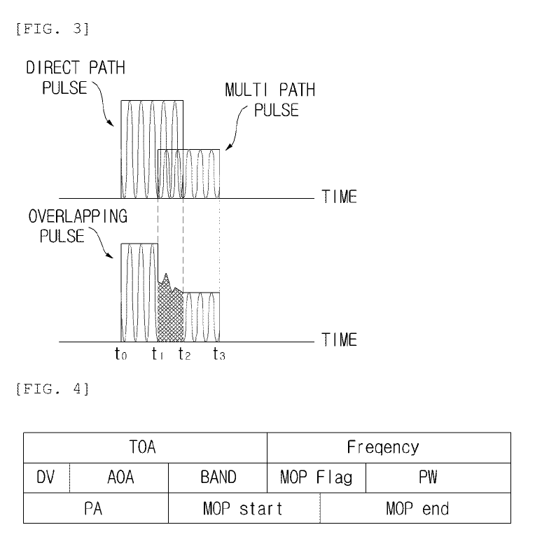

FIG. 3 is a diagram showing a shape where the MOP occurs due to the direct path signal and the multi path signal. Referring to FIG. 3, the start time (the start time of the received pulse) of the direct path signal is to, the start time of the MOP is t1, the end time of the MOP is t2, and the end time (the end time of the received pulse) of the multi path signal is t3. When the time between the start time t1 of the MOP and the end time t2 thereof is compared with the time t0 to t1 before the start time t1 of the MOP and the time t2 to t3 after the end time t2 of the MOP, the phase, amplitude, and frequency characteristics are remarkably changed in the time between the start time t1 of the MOP and the end time t2 thereof due to the modulation.

The determination whether the MOP occurs due to the direct path signal and the multi path signal may be determined as the unintended MOP due to the multi path signal when the start time of the MOP is lagged as compared to the start time t0 of the direct path signal. When the start time of the MOP is equal to the start time t0 of the direct path signal, the reason is that the received signal may be considered as the originally modulated signal rather than the unintended MOP due to the multi path signal.

If it is determined that the MOP occurs due to the direct path signal and the multi path signal, the start time and the end time of the MOP are detected, which may be performed as follows. As described above, when the times before and after the occurrence time of the MOP are compared in the occurrence time of the MOP, the phase, the signal strength, the frequency characteristics are changed. Therefore, the signal is sampled at the predetermined interval (for example, 500 MHz), the in-phase component and the quadrature component are extracted for each sample and the phase, the signal strength, and the frequency characteristics are extracted by using the extracted component. It can confirm the time when at least one of the phase, the signal strength, and the frequency of the sample are suddenly changed. The time when the sudden change first occurs may be detected as the start time t1 of the MOP and then, the time when the sudden change occurs may be detected as the end time t2 of the MOP. Whether the phase, the signal strength, and the frequency are suddenly changed may be determined according to whether the difference between the consecutively measured values for a predetermined short period exceeds the predetermined reference value.

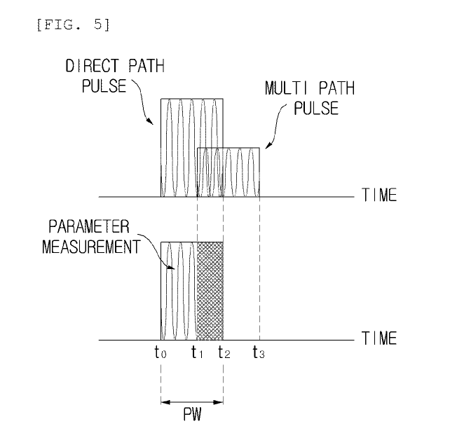

After step 230, the information on the occurrence or not of the MOP and the pulse description word (PDW) including the start time and the end time of the MOP is generated (S240). In other words, the PDW generated in the present exemplary embodiment further includes the information on the occurrence or not of the MOP and the start time and the end time of the MOP, in addition to the time of arrival (TOA), the frequency, the direction vector (DV), the angle of arrival (AOA), the BAND, the pulse width (PW), the pulse amplitude (PA), or the like, which are information included in the existing PDW. FIG. 4 shows the structure of the PDW according to the exemplary embodiment of the present invention. Referring to FIG. 4, an MOP flag represents the occurrence or not of MOP (0 or 1), an MOP start represents the start time of MOP, and an MOP end represents the end time of MOP.

After step 240, among the parameters for discriminating the signals using the in-phase component and the quadrature component of the samples of the signal in the time from the start time t0 of the received pulse to the start time t1 of the MOP, the signal strength, the frequency, and the phase are extracted (S250). Described with reference to FIG. 5, the time from the start time t0 of the received pulse to the start time t1 is the valid time and the signal strength, the frequency, and the phase parameter are extracted by using the in-phase component and the quadrature component in the valid time. If the valid time is after the starting time t1 of the MOP (for example, the end time t3 of the received pulse) and the signal strength, the frequency, and the phase parameter are extracted by using the interface component and the quadrature component in the time, the accurate parameter values may not be extracted due to the MOP and the multi path signal. Therefore, the faulty discrimination or no discrimination is caused. The signal strength, the frequency, and the phase obtained in step 240 are written in the PDW.

After step 250, the time from the start time t0 of the received pulse to the end time t2 of the MOP is extracted as the pulse width of the signal. Since the interested signal in the electronic intelligence receiver is the direct path signal, the pulse width of the direct path signal should be extracted. Since it cannot appreciate the end time of the direct path signal when the MOP occurs, the end point t2 of the MOP is instead considered as the end time of the direct path signal and the pulse width of the signal is extracted. Referring to FIG. 5, as described above, the signal strength, the frequency, the phase parameter are extracted in the time t0 to t1 as the valid time, while the pulse width PW of the signal is extracted as the time from the start time t0 of the received pulse to the end time t2 of the MOP. The pulse width obtained at step S250 is also written in the PDW.

The parameters extracted at steps S240 and S250, that is, the signal strength, the frequency, the phase, the pulse width are used to discriminate any kinds of threat signals based on the information stored in the library provided in the electronic intelligence receiver in advance.

Meanwhile, the exemplary embodiments of the present invention can be prepared by programs running in a computer and can be implemented by a general-purpose digital computer that runs the programs using a recording medium readable with the computer. The recording medium readable with the computer includes magnetic storage media (for example, ROM, floppy disk, hard disk, etc.), optical reading media (for example, CD-ROM, DVD, etc.), and storage media such as carrier wave (for example, transmission through Internet).

Hitherto, the present invention has been described based on the exemplary embodiments. It will be appreciated by those skilled in the art that various modifications, changes, and substitutions can be made without departing from the essential characteristics of the present invention. Accordingly, the exemplary embodiments disclosed in the present invention and the accompanying drawings are used not to limit but to describe the spirit of the present invention. The protection scope of the present invention must be analyzed by the appended claims and it should be analyzed that all spirits within a scope equivalent thereto are included in the appended claims of the present invention.

What is claimed is:

1. A signal discriminating method of an electronic intelligence receiver, comprising:
(a) detecting a start time and an end time of modulation on pulse (MOP) due to a direct path signal and a multi path signal from a received signal; and
(b) extracting at least one of signal strength, frequency, and phase by using in-phase component and quadrature component of the signal in a time from a start time of the signal to a start time of the MOP.

2. The method of claim 1, further comprising (c) extracting the time from the start time of the signal to the end time of the MOP as the pulse width of the signal.

3. The method of claim 2, further comprising determining the occurrence or not of the MOP.

4. The method of claim 1, wherein the step (a) detects the start time and the end time of the MOP based on the change in signal strength, frequency, and phase extracted using the in-phase component and quadrature component of the signal over the time.

5. The method of claim 4, wherein the step (a) detects the first sudden change time of at least one of the extracted signal strength, frequency, and phase as the start time of the MOP and the second sudden change time thereof as the end time of the MOP.

6. The method of claim 3, further including generating a pulse description word (PDW) including the information on the extracted signal strength, frequency, phase, and pulse width.

7. The method of claim 6, wherein the PDW further includes information on the occurrence or not of MOP and the start time and the end time of MOP.

8. A recording medium readable with a computer recording a program for executing the signal discriminating method of an electronic intelligence receiver according to in claim 1.
